(19) United States
(12) Patent Application Publication
(10) Pub. No.: US 2025/0167037 A1
(43) Pub. Date: May 22, 2025

(54) WAFER CHUCK ASSEMBLY

(71) Applicant: Taiwan Semiconductor Manufacturing Co., Ltd., Hsinchu (TW)

(72) Inventors: Chia-Hsi Wang, Xihu Township (TW); Yen-Yu Chen, Taichung City (TW); Yi-Hu Lo, Taichung City (TW); Pei-Shih Tsai, Hsinchu (TW); Zong-Kun Lin, Changhua (TW)

(21) Appl. No.: 18/512,146

(22) Filed: Nov. 17, 2023

(51) Int. Cl. H01L 21/687; H01L 21/306; H01L 21/67

(52) U.S. Cl. CPC H01L 21/6875; H01L 21/30604; H01L 21/67253; H01L 21/68721

(57) ABSTRACT

A wafer chuck assembly is provided. In one embodiment, the chuck assembly comprises a hub, a plurality of arms mounted to the hub and a plurality of holders. Each arm extends outwardly from the hub, and each arm has a proximal end adjacent the hub and a distal end remote from the hub. Each holder is mounted at the distal end of each respective arm, and each holder has a plurality of support pins configured to support a wafer.

### BACKGROUND

Edge Bevel Removal, commonly known as EBR, is a process specifically designed to remove unwanted thin films from the edges of wafers. EBR typically employs specific chemical agents to remove material from the edges of the wafer. In this process, the wafer is secured and rotated, while the chemical agent is sprayed along the edge portions. The chemical agent reacts with the excess material at the edges, making it easier to remove. Subsequently, these reaction products are rinsed off.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of the wafer chuck assembly, in accordance with some embodiments of the present disclosure.

FIG. 2 is a schematic view of the holder of the wafer chuck assembly, in accordance with some embodiments of the present disclosure.

FIG. 3 is a schematic top view of the wafer chuck assembly, in accordance with some embodiments of the present disclosure.

FIG. 4 is a schematic view of the wafer chuck assembly with the measurement system, in accordance with some embodiments of the present disclosure.

FIG. 5A and FIG. 5B are schematic views of the monitor system of the wafer chuck assembly, in accordance with some embodiments of the present disclosure.

FIG. 6A and FIG. 6B show various embodiments of the holder of the wafer chuck assembly.

FIG. 7 is a flow chart of the electrochemical plating process, in accordance with some embodiments of the present disclosure.

FIG. 8 is a flow chart of the edge bevel removal step, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that may exist alone or in other combinations of features; the scope of the disclosure being defined by the claims appended hereto.

The manufacturing of integrated circuits generally involves the deposition of one or more layers of metal onto the effective circuit areas of a wafer. The conductive interconnects on the integrated circuits typically take the form of trenches and vias. These trenches and vias are usually formed by damascene or dual-damascene processes. Electro-chemical plating (ECP) may be used to form small embedded metal features due to its ability for bottom-up filling and the excellent conductive characteristics of the deposited film.

During the electroplating process, metal layers may be deposited in areas outside the effective circuit region, such as the edge areas of the wafer. For example, prior to electroplating, a metal layer is usually deposited to serve as a seed layer to facilitate subsequent electroplating operations. This can be done using methods like Physical Vapor Deposition (PVD) and may result in the seed layer covering edge areas of the wafer, such as the front edge area and the sides. In subsequent electroplating processes, additional electroplated metal layers are further formed on top of the seed layer.

Embodiments such as those discussed below provide an Edge Bevel Removal (EBR) process on the wafer's edge area after electroplating to remove both the seed layer and the electroplated metal layer.

The EBR process may utilize a wafer chuck assembly which achieves the effect of stably holding and rotating the wafer. Further, the component of the wafer chuck assembly configured to be in contact with and support the wafer may be wear-resistant, thus reducing the frequency of replacement and consequently achieving an overall improvement in wafer production efficiency.

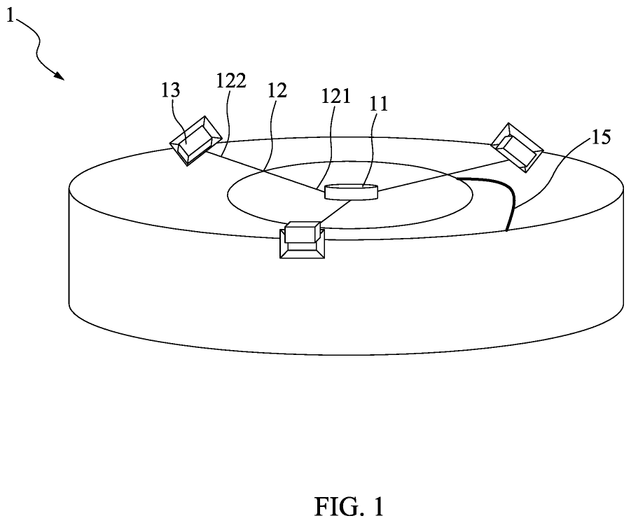

FIG. 1 is a schematic side view of the wafer chuck assembly 1, in accordance with some embodiments. As shown in FIG. 1, the wafer assembly 1 may include a rotatable center hub 11, a plurality of support arms 12, a plurality of holders 13 and a nozzle 15. The support arms 12 may be mounted to the rotatable center hub 11 and extend outwardly from the rotatable center hub 11. That is, each of the support arms 12 may include a proximal end 121 adjacent the rotatable center hub 11 and a distal end 122 remote from the rotatable center hub 11, and the support arm 12 may extend outward between the proximal end 121 and the distal end 122. In some embodiments, the wafer chuck assembly 1 includes three support arms 12, and the support arms 12 may be positioned at radial intervals of 120°, 240°, and 360° around the rotatable center hub 11. This arrangement ensures stability and balance during the wafer handling process.

Further, referring to FIG. 1, each of the holders 13 may be mounted at the distal end 122 of the support arm 12. When a semiconductor wafer is provided to the wafer chuck assembly 1, the holders 13 may be configured to engage and/or hold the semiconductor wafer. When the rotatable center hub 11 rotates, it drives the support arms 12 and the holders 13 mounted on the support arms 12 to rotate as well, thereby causing the semiconductor wafer engaged and/or held by the holders 13 to rotate along with them. In some embodiments, the wafer chuck assembly 1 may be designed to securely hold the semiconductor wafer in the appropriate position and the semiconductor wafer can be rotated at various speeds ranging from approximately 0 RPM to approximately 6000 RPM through the rotatable center hub 11. In some embodiments of the present disclosure, the rotatable center hub 11 may provide a rotation rate ranging between approximately 0 RPM and approximately 6000 RPM. Generally speaking, while performing the Edge Bevel Removal (EBR) process the semiconductor wafer may be rotated in a range from approximately 0 RPM to approximately 2500 RPM, such as in a range from approximately 100 RPM to approximately 1500 RPM, or such as in a range from approximately 500 RPM to approximately 1300 RPM.

The nozzle 15 may have an outward-facing spray port, from which the liquid etchant may be sprayed on the semiconductor wafer to remove metal near the edge of the semiconductor wafer. For example, the liquid etchant may be applied to the edge of the semiconductor wafer in a fine stream, forming a thin viscous layer close to its point of application on the semiconductor wafer, thereby preventing or reducing the liquid etchant from splattering onto the interior of the semiconductor wafer and removing metal from the active circuit area. Due to the radial speed component with which the liquid etchant is applied and the centripetal acceleration effects of rotating wafer, this thin viscous layer flows outward, streaming downward over the side edges, and may also flow to the backside of the semiconductor wafer, thus achieving the purpose of metal removal from the wafer edge. In some embodiments, the EBR process is performed under the following conditions: for wafers with a diameter of approximately 290 mm to approximately 310 mm, the liquid etchant is dispersed at a rate of approximately 0.2 ml/sec to approximately 3 ml/sec, such as approximately 0.3 ml/sec to approximately 0.4 ml/sec, delivering a total of approximately 3 ml to approximately 15 ml of liquid etchant. In some implementations, the liquid etchant may be supplied through two or more operations with different flow rates. For example, in a first operation, approximately 1 ml to 2 ml of liquid etchant is provided at a rate of approximately 0.4 ml/sec to 0.5 ml/sec, followed by a second operation where approximately 8 ml to 12 ml of liquid etchant is provided at a rate of approximately 0.2 ml/sec to 0.4 ml/sec.

The etchant may include an acid and oxidizer. Examples of acids include sulfuric acid, hydrohalic acids, chromic acid and nitric acid. Examples of oxidizers include perchloric acid, hydrofluoric acid and sulfuric acid In some embodiments, the etchant for copper EBR may be a solution of H₂SO₄ (sulfuric acid) and H₂O₂ (hydrogen peroxide) in water. In some embodiments, the etchant comprises between about 15% to 25% H₂SO₄ by weight and 20% to 35% H₂O₂ by weight. Near neutral and alkaline etchants which tend to complex with the dissolved metal can also be employed, such as combinations of glycine or ethylene diamine and hydrogen peroxide at a pH of around 9. Generally, the liquid etchant may be selected according to the physical properties of the etching system, such as surface tension, contact angle, and viscosity.

After the required amount of liquid etchant has been applied to the edge of the wafer, deionized water may be applied to the front side of the wafer as a post-EBR rinse through the nozzle 15. Deionized water may be applied to the entire wafer as a whole. This application of deionized water may continue through the subsequent operations of backside etching and backside rinsing so as to protect the wafer from any extraneous backside etchant spray and damage. While the deionized water is applied, the dispense arm moves the etchant nozzle away from the wafer.

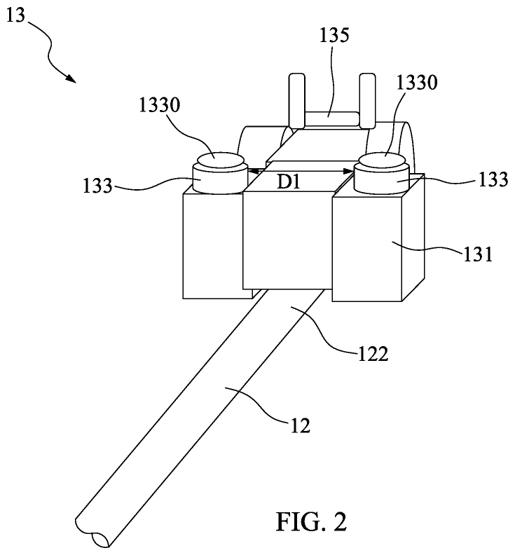

FIG. 2 is a schematic view of the holder 13 of the wafer chuck assembly 1, in accordance with some embodiments. As abovementioned, the holder 13 may be at the distal end 122 of the support arm 12. The holder 13 may include a base 131, two support pins 133-1/133-2 (collectively referred to as support pins 133) and an alignment member 135. As shown in FIG. 2, the support pins 133 may be disposed on the base 131 of the holder 13. When the semiconductor wafer is provided in the wafer chuck assembly 1 and held/engaged by the holders 13, the support pins 133 may directly contact and support the bottom surface of the semiconductor wafer. The semiconductor wafer rides on support pins 133 (located on support arms 12) by static friction. In some embodiments, the support pins 133 are located from about 5 to 20 millimeters, such as about 5 to 10 millimeters, in from the edge of semiconductor wafer. The size/design of the support pins supplies enough friction to keep the wafer from flying off the chuck if it is aligned slightly off center (e.g. when aligned to the tolerance of the specification of the edge bevel removal process), reduce or prevent slippage as the wafer is accelerated (e.g., at a rate of 50 to 300 rpm/sec (such as 100 rpm/sec)) from rest to the EBR rotation rate, and prevent/reduce shedding or dislodging particles.

To secure the wafer and to reduce/prevent slippage, each holder 13 may be equipped with multiple support pins 133 to support and make contact with the bottom of the semiconductor wafer. This ensures that the semiconductor wafer remains stable during the EBR rotation process. In some embodiments, the support pin 133 may include a support pad 1330. When the support pins 133 support the semiconductor wafer, the support pads 1330 directly contact the bottom surface of the semiconductor wafer. In some embodiments, the support pad 1330 may be replaceable. In some embodiments, the two support pins 133 may be spaced apart by a distance D1 that may be approximately equal to or greater than a width of the support pins 133 or a diameter of the support pads 1330.

Additionally, to prevent or reduce shedding or dislodging of particles, the support pin 133 may be resistant to chemical corrosion and wear. That is, the support pad 1330 may be resistant to chemical corrosion and wear. In some embodiments, the support pad 1330 of the support pin 133 may include an FFKM (perfluoroelastomer) elastomer. That is, the support pin 133 may include an FFKM (perfluoroelastomer) material. An FFKM (perfluoroelastomer) material is a type of synthetic rubber that exhibits a range of characteristics such as Chemical Resistance (e.g., FFKM has excellent chemical resistance due to the complete fluorination of its molecular structure and can withstand exposure to a wide range of aggressive chemicals, acids, and solvents) High-Temperature Tolerance (e.g., FFKM can operate effectively at temperatures up to 300° C. (572° F.), retaining its mechanical properties even under extreme heat), Low-Temperature Flexibility (e.g., certain grades of FFKM also maintain their elasticity at extremely low temperatures, making them suitable for a broad range of operating conditions). Example FFKM elastomers include Kalrez® perfluorinated elastomer, a Chemraz® perfluorinated elastomer, a Parofluor™ perfluorinated elastomer, a Hifluor™ perfluorinated elastomer, a Simriz® perfluorinated elastomer, an Isolast® perfluorinated elastomer and a Perlast® perfluorinated elastomer. When the support pad 1330 are made from FFKM material, it significantly reduces the pad wear and extends the frequency of pad replacement. The replacement cycle can be extended, such as from once every two weeks to once every 12 weeks.

The alignment members 135 may be used to facilitate proper alignment of the semiconductor wafer on the wafer chuck assembly 1 as the semiconductor wafer is delivered to wafer chuck assembly 1.

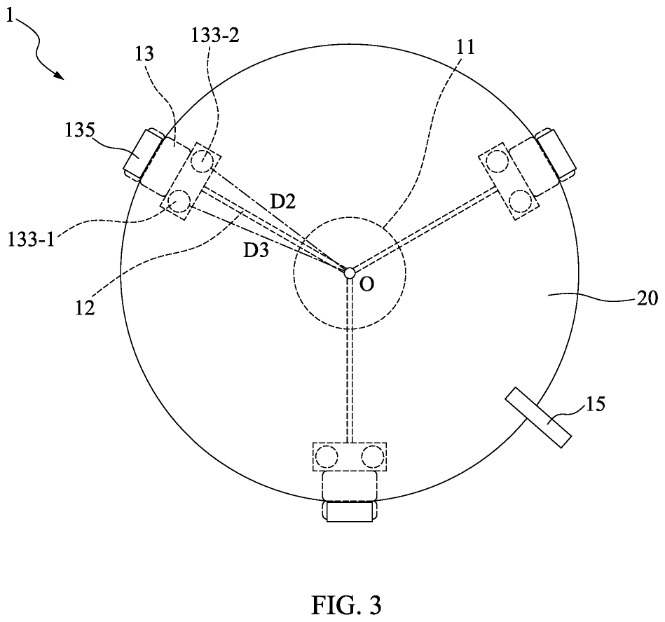

Referring to FIG. 3, a top-down view illustrates a semiconductor wafer 20 provided to the wafer chuck assembly 1 and held by the holders 13 of the wafer chuck assembly 1. The wafer chuck assembly 1 may have a plurality of support arms 12 outwardly extending from the rotatable center hub 11 and underneath the semiconductor wafer 20. The holder 13, which may be mounted to the distal end 122 of the support arm 12, may be at least partially positioned beneath the semiconductor wafer 20. The holder 13 may be include two support pins 133-1/133-2. The holders 13 may be configured to hold and/or engage the semiconductor wafer 20, and the two support pins 133-1/113-2 of each holder 13 are configured to support and make contact with the bottom surface of the semiconductor wafer 20. That is, there is a two-point contact between the bottom surface of the semiconductor wafer and each of the holders 13. Because each holder 13 makes two-point contact with the bottom surface of the semiconductor wafer 20 to support and hold it, the wafer chuck assembly 1 can more effectively maintain semiconductor wafer 20 stability during the implementation of the EBR process.

In some embodiments, the support pins 133-1/113-2 may be positioned side by side. Referring to FIG. 3, a horizontal distance D2 from the support pin 133-1 to a center of the semiconductor wafer 20 may be substantially equal to a horizontal distance D3 from the support pin 133-2 to the center of the semiconductor wafer 20. In this way, if one of the two support pins 133-1, 133-2 becomes excessively worn, the other support pin 133-1, 133-2 may continue to support and make contact with the bottom surface of the semiconductor wafer 20 at approximately the same horizontal level, thereby maintaining the wafer's stability.

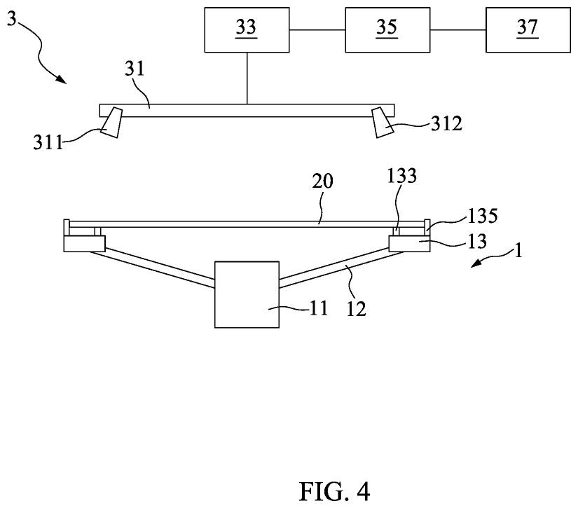

FIG. 4 is a schematic view of the wafer chuck assembly 1 with a measurement system 3, in accordance with some embodiments. As shown in FIG. 4, the measurement system 3 may include an image sensor 31, a controller 33, a computer 35 and an inspection equipment 37. In some embodiments, the image sensor 31 may include a CMOS image sensor. The image sensor 31 may include two CCD cameras 311, 312. The two CCD cameras may each be approximately aligned with the edge regions of the semiconductor wafer 20. When the wafer chuck assembly 1 rotates the semiconductor wafer 20 by rotating the rotatable center hub 11 and the EBR (Edge Bevel Removal) process is performed, the two CCD cameras 311 and 312 may capture image information of the edge region of the semiconductor wafer 20, including changes in the wafer's edge regions as well as the wafer's position during the EBR process.

The controller 33 may be electrically connected to the image sensor 31. In some embodiments, the controller 33 may include a MCU controller. The controller 33 is configured to control the CCD cameras 311 and 312 of the image sensor 13. The image sensor 31 may transmit the image information, which may be captured by the CCD cameras 311 and 312, to the controller 33. In some embodiments, the image information captured by the CCD cameras 311 and 312 may be the colorful image information. The controller 311 may convert the colorful image information to grayscale image information and transmit the grayscale image information to the computer 35

After receiving the grayscale image information provided by the controller 33, the computer 35 may calculate the width data of the edge region of the semiconductor wafer 20 based on the grayscale image data. In some embodiments, the computer 35 includes a monitor which can instantly display grayscale image information about the edge region of the semiconductor wafer 20 and relevant information about that edge region of the semiconductor wafer 20. Further, the computer 35 may transmit the calculated width data of the edge region of the semiconductor wafer 20 to the inspection equipment 37 and the inspection equipment may determine whether the edge region of the semiconductor wafer 20 meets the standard based on the width data from the computer 35. In some embodiments, the inspection equipment 37 may record the width data of the edge region of the semiconductor wafer 20.

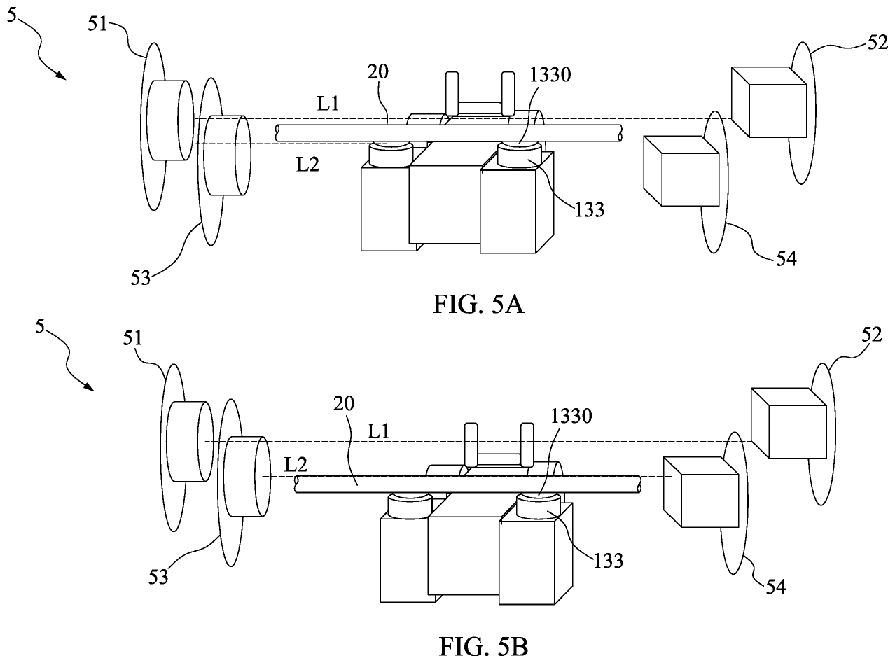

As shown in FIG. 5A and FIG. 5B, the wafer chuck assembly may include a monitor system 5. In some embodiments, the monitor system 5 may include a controller and two pairs of laser transmitters and receivers, such as a first laser transmitter 51 and receiver 52 pair and a second laser transmitter 53 and receiver 54 pair. The two pairs of laser transmitters and receivers may be electrically connected to the controller. The laser transmitters 51, 53 may be positioned on opposing sides of the receivers 52, 54 relative to the holder 13. The laser transmitter 51 may be substantially aligned with the receiver 52. Thus, the laser transmitter 51 is configured to emit a laser light L1 toward the receiver 52, and the receiver 52 is configured to receive the laser light L1 from the laser transmitter 51. Moreover, the laser transmitter 53 may be substantially aligned with the receiver 54. Thus, the laser transmitter 53 is configured to emit a laser light L2 toward the receiver 54, and the receiver 54 is configured to receive the laser light L2 from the laser transmitter 53. Further, the laser transmitter 53 may be substantially aligned with the support pads 1330 of the support pins 133 of the holder 13 as well. Thus, in some cases, the laser light L2 emitted by the laser transmitter 53 may be obstructed by the support pads 1330 of the support pins 133, and as a result, the receiver 54 is unable to receive the laser light L2 emitted by the laser transmitter 53.

FIG. 5A shows that the support pads 1330 of the support pins 133 of the holder 13 are still in a qualified and usable condition. As shown in FIG. 5A, the semiconductor wafer 20 may be supported by the support pins 133 of the holder 13 and the bottom surface of the semiconductor wafer 20 may be in contact with the support pads 1330 of the support pins 133. The laser transmitter 51 may emit the laser light L1 over the semiconductor wafer 20 and the receiver 52 may receive the laser light L1 from the laser transmitter 51. Further, the laser transmitter 53 may emit the laser light L2 toward the receiver 54. Since the support pads 1330 of the support pins 133 of the holder 13 are still in a qualified and usable condition, the support pads 1330 of the support pins 3 may elevate the semiconductor wafer 20 to a certain height and the laser light L2 may pass beneath the semiconductor wafer 20. However, the laser transmitter 53 may be substantially aligned with the support pads 1330 of the support pins 133, thus the support pads 1330 of the support pins 133 may block the laser light L2 emitted from the laser transmitter 53 and the receiver 54 may be unable to receive the laser light L2. That is, when the receiver 52 can receive the laser light L1 from the laser transmitter 51 while the receiver 54 cannot receive the laser light L2, this indicates that the support pads 1330 of the support pins 133 are still in a qualified and usable condition.

FIG. 5B shows that the support pads 1330 of the support pins 133 of the holder 13 have worn down to a condition where they need to be replaced. When the support pads 1330 of the support pins 133 are worn down to the point where it can no longer be used and needs to be replaced, the height of the semiconductor wafer 20 they support may drop to a level that allows the laser light L2 emitted by the laser transmitter 53 to pass above the semiconductor wafer 20 and be received by the receiver 54. That is, when the receiver 52 can receive the laser light L1 from the laser transmitter 51 while the receiver 54 can receive the laser light L2, this indicates that the support pads 1330 of the support pins 133 of the holder 13 have worn down to a condition where they need to be replaced.

In addition, as above mentioned, the laser L1 emitted from the laser transmitter 51 may pass over the semiconductor wafer 20 when the semiconductor wafer 20 is supported by the support pins 133 of the holder 13. During the process of transferring the semiconductor wafer 20 away from the holder 13 or placing the semiconductor wafer 20 onto the holder 13, the semiconductor wafer 20 may briefly block the laser L1, so that the user can know the movement of the semiconductor wafer 20.

When the receiver 52 receives or does not receive the laser L1 emitted by the laser transmitter 51 and/or when the receiver 54 receives or does not receive the laser L2 emitted by the transmitter 53, the controller can provide relevant information accordingly. For example, when the receiver 54 receives the laser L2 emitted by the transmitter 53, the controller may send a notification message or an alarm to inform the user that the support pads 1330 of the support pins 133 of the holder 13 have worn down to a condition where they need to be replaced.

In some embodiments, the measurement system 3 and the monitor system may be independent of each other.

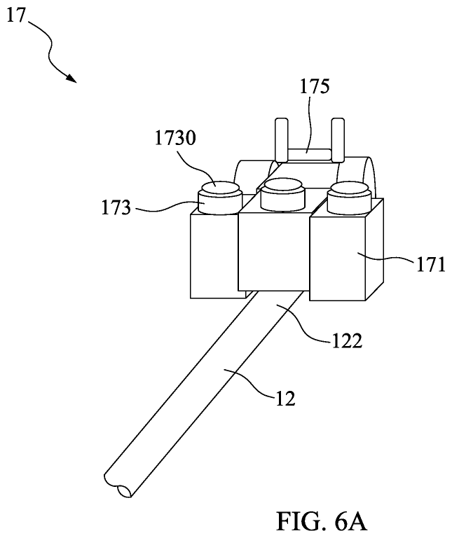

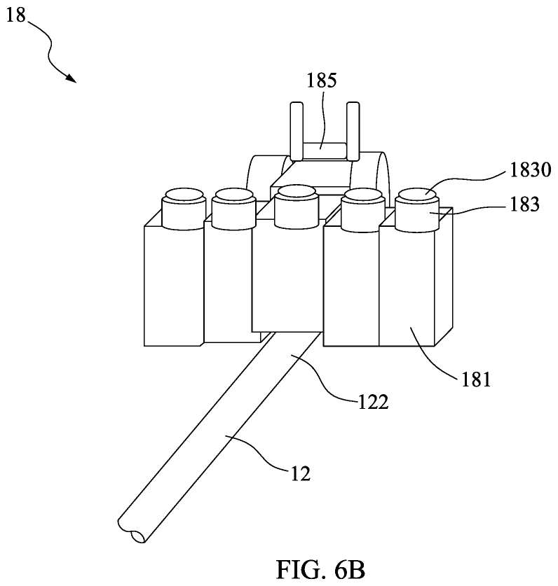

FIG. 6A shows an embodiment of the holder 17 which may be mounted to the distal end 122 of the support arm 12 of the wafer chuck assembly 1. The holder 17 may include a base 171, three support pins 173 and an alignment member 175. The support pins 173 may be disposed on the base 171 of the holder 17. In some embodiments, these three support pins 173 may be substantially aligned in a row along a width of the base 171. When the semiconductor wafer is provided in the wafer chuck assembly 1 and held/engaged by the holders 17, the support pins 173 may contact and support the bottom surface of the semiconductor wafer. The semiconductor wafer may ride on support pins 173 (located on support arms 12) by static friction. The support pins 173 may be located from about 5 to 20 millimeters, such as about 5 to about 10 millimeters, in from the edge of semiconductor wafer. In some embodiments, the support pin 173 may include a support pad 1730 on its top. That is, when a wafer is supported by the support pin 173 of the holder 17, the support pads 1730 may directly contact a bottom surface of the wafer.

Since the holder 17 may include three support pins, there is a three-point contact between the bottom surface of the semiconductor wafer and each of the holders 17 when the semiconductor wafer is supported and/or held by the holders. Because each holder 17 makes three-point contact with the bottom surface of the semiconductor wafer to support and hold it, the wafer chuck assembly 1 can more effectively maintain semiconductor wafer stability during the implementation of the EBR (Edge Bevel Removal) process.

Further, the support pad 1730 may be resistant to chemical corrosion and wear. In some embodiments, the support pad 1730 of the support pin 173 may include an FFKM (perfluoroelastomer) elastomer. That is, the support pin 173 may include an FFKM (perfluoroelastomer) material.

FIG. 6B shows another embodiment of the holder 18 which may be mounted to the distal end 122 of the support arm 12 of the wafer chuck assembly 1. The holder 18 may include a base 181, five support pins 183 and an alignment member 185. The support pins 183 may be disposed on the base 181 of the holder 18. In some embodiments, the support pins 183 may be substantially aligned in a row along a width of the base 181. When the semiconductor wafer is provided in the wafer chuck assembly 1 and held/engaged by the holders 18, the support pins 183 may contact and support the bottom surface of the semiconductor wafer. The semiconductor wafer may ride on support pins 183 (located on support arms 12) by static friction. The support pins 183 may be located from about 5 to about 20 millimeters, such as about 5 to about 10 millimeters, in from the edge of semiconductor wafer. In some embodiments, the support pin 183 may include a support pad 1830 on its top. That is, when a wafer is supported by the support pin 183 of the holder 18, the support pads 1830 may directly contact a bottom surface of the wafer.

Since the holder 18 may include five support pins, there is a five-point contact between the bottom surface of the semiconductor wafer and each of the holders 18 when the semiconductor wafer is supported and/or held by the holders 18. Because each holder 18 makes five-point contact with the bottom surface of the semiconductor wafer to support and hold it, the wafer chuck assembly 1 can more effectively maintain semiconductor wafer stability during the implementation of the EBR (Edge Bevel Removal) process.

Further, the support pad 1830 may be resistant to chemical corrosion and wear. In some embodiments, the support pad 1830 of the support pin 183 may include an FFKM (perfluoroelastomer) elastomer. That is, the support pin 183 may include an FFKM (perfluoroelastomer) material.

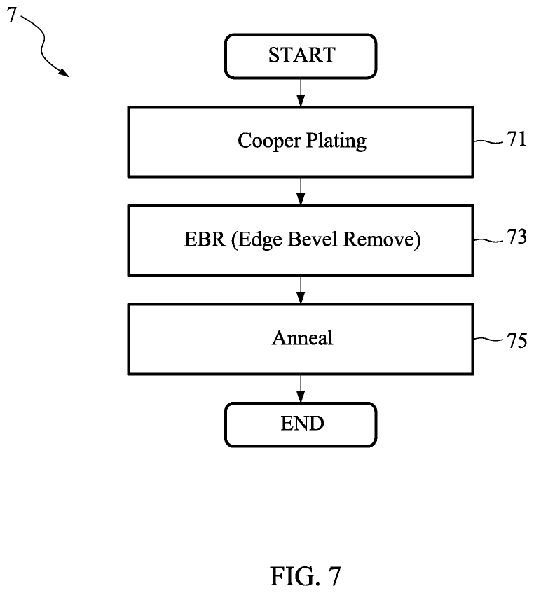

FIG. 7 is a flow chart of the electrochemical plating process 7, in accordance with some embodiments. The electrochemical plating (ECP) 7 is a process that utilizes electrochemical reactions to perform electroplating on the surface of materials. The process of ECP 7 may include a copper electroplating step 71, an edge bevel removal step 73, and an annealing step 75.

The copper plating step 71 may involve the electrochemical deposition of a copper layer on the substrate (semiconductor wafer). The copper plating step 71 may be the initial step in the ECP process 7. It may involve immersing the substrate into an electrolyte solution containing copper ions. By applying a specific voltage to the substrate surface, the copper ions are reduced and deposited as a copper metal layer. This electrochemical reaction allows for the formation of a uniform and adherent copper coating on the substrate. The copper plating step 71 provides conductivity and acts as a seed layer for subsequent plating processes.

The edge bevel removal step 73 eliminates/reduces beveled edges that may have formed during the plating process. The beveled edges can cause difficulties in subsequent processes. In some embodiments, the edge bevel removal step 73 may include a chemical etching method. The chemical etching method may utilize a chemical solution to selectively remove the beveled portion of the substrate to provide a flatter and more even surface for further processing.

The annealing step 75 is related to a heat treatment process that relieves stress and improves the crystal structure of the copper layer providing better conductivity and mechanical properties. Annealing involves heating the copper metal to a specific temperature and then cooling it slowly. This controlled heating and cooling process allows for the redistribution of atoms and the elimination of internal stresses, resulting in a more stable and structurally sound copper layer. Annealing also enhances the electrical and mechanical properties of the copper, making it more suitable for subsequent processing steps.

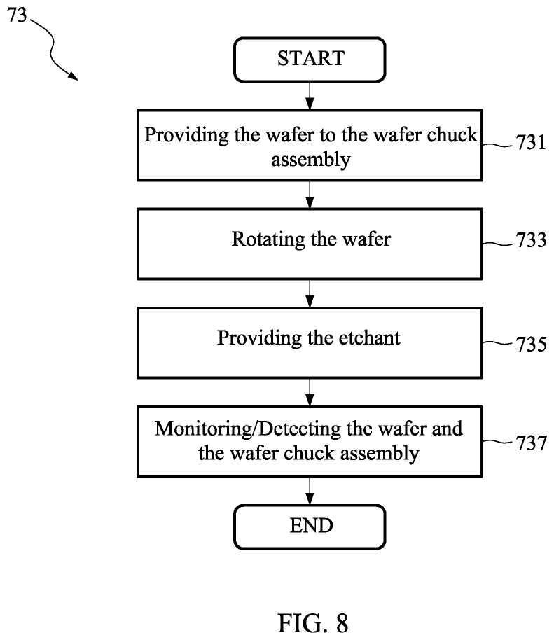

FIG. 8 is a flow chart of the edge bevel removal step 73 of FIG. 7, in accordance with some embodiments.

At operation 731, the semiconductor wafer 20 may be placed onto the wafer chuck assembly 1. The holders 13 of the wafer chuck assembly 1 are responsible for securely holding the semiconductor wafer 20 in place. The support pins 133 of each holder may provide support to the bottom surface of the semiconductor wafer 20. Additionally, the alignment member 135 may be included in each holder 13 to engage the edge of the semiconductor wafer 20, ensuring a secure hold. To ensure proper support, each holder 13 includes the multiple support pins 133 that are configured to support the bottom surface of the semiconductor wafer 20. These support pins 133 may be equipped with the support pads 1330 that may make direct contact with the bottom surface of the semiconductor wafer 20. This design allows for multiple points of contact between the semiconductor wafer 20 and each holder 13 when it is placed and supported by the wafer chuck assembly 1.

In some embodiments, the support pad 1330 of the support pin 133 may include a FFKM (perfluoroelastomer) material. The FFKM support pads 1330 may ensure a reliable and durable contact between the support pins 133 and the semiconductor wafer 20, further enhancing the stability and precision of the wafer chuck assembly 1.

At operation 733, the semiconductor wafer 20 may be positioned onto the holders 13, which are connected to the rotatable center hub 11 through support arms 12. Once the semiconductor wafer 20 is in place, the rotatable center hub 11 may be activated and begin to rotate. As a result, the holders 13, along with the semiconductor wafer 20, also start to rotate around the rotatable center hub 11.

To ensure the stability of the semiconductor wafer 20 during the rotation process, each holder 13 may be equipped with multiple support pins 133. These support pins 133 are positioned to provide multiple-point contact between the bottom surface of the semiconductor wafer 20 and the holder 13. This design feature ensures that the semiconductor wafer remains securely held in place and does not wobble or shift during the rotation. Any instability or movement of the wafer during this process can lead to uneven material removal or damage to the wafer. By utilizing the multiple support pins 133 on each holder 13, the semiconductor wafer 20 may be held stably in place, allowing for a precise and controlled rotation during the EBR process.

At operation 735, the liquid etchant may be applied to the edge region of the rotating semiconductor wafer 20 through the nozzle 15, thus removing the metal located in the edge region of the semiconductor wafer 20. The liquid etchant is evenly distributed in the edge region of the semiconductor wafer 20, avoiding/reducing excessive or insufficient removal of metal, and to prevent/reduce metal from splashing onto the active area of the semiconductor wafer 20.

The etchant may include an acid and oxidizer. Examples of acids that are useful include sulfuric acid, hydrohalic acids, chromic acid and nitric acid. Examples of oxidizers include perchloric acid, hydrofluoric acid and sulfuric acid In some embodiments, the etchant for copper EBR may be a solution of H₂SO₄ (sulfuric acid) and H₂O₂ (hydrogen peroxide) in water. In some embodiments, the etchant comprises between about 15% to 25% H₂SO₄ by weight and 20% to 35% H₂O₂ by weight.

At operation 737, the measurement system 3 may detect the semiconductor wafer 20 and the monitoring system 5 may monitor the holders 13 of the wafer chuck assembly when the holders 13 of the wafer chuck assembly 1 rotates the semiconductor wafer 20 and/or the liquid etchant is applied to the edge region of the semiconductor wafer 20.

The measurement system 3 may be equipped with the image sensor 31 that is configured to capture detailed image information of the edge region of the semiconductor wafer 20. Further, the measurement system 3 may also include the controller 33, the computer 35 and the inspection equipment 37. The controller 33 may convert the image information captured by the image sensor 31 into the information that could be calculated by the computer 35. The computer may calculate the width data wafer's edge region based on the information from the controller. The inspection equipment 37 may determine whether the wafer's edge region meets the standard based on the width data from the computer 35. That is, the measurement system 3 enables efficient and precise analysis of the wafer's edge regions and its position during the EBR process.

The measurements system 3 may include the monitor system 5, which may include two pairs of laser transmitters and receivers. These components may be positioned on opposing sides of the holder 13. The first pair includes laser transmitter 51 and receiver 52, while the second pair consists of laser transmitter 53 and receiver 54. The laser transmitter 51 may emit laser light L1 towards the receiver 52, and the receiver 52 may receive this light. Similarly, the laser transmitter 53 may emit the laser light L2 towards receiver 54, and receiver 54 may receive this light.

In some embodiments, the positions of the laser transmitter 51 and the receiver 52 may be higher than the positions of the laser transmitter 53 and the receiver 54. This positioning allows for effective detection and monitoring of the support pads 1330 of the support pins 133.

When the support pads 1330 of the support pins 133 are in good condition, the laser light L1 from the laser transmitter 51 may pass above the semiconductor wafer 20 and be received by the receiver 52. However, the laser light L2 from the laser transmitter 53 may pass below the semiconductor wafer 20 and be obstructed by the support pads 1330. As a result, the receiver 52 is unable to receive the laser light L2.

On the other hand, when the support pads 1330 have worn down and require replacement, the laser light L1 from the laser transmitter 51 may still pass above the semiconductor wafer 20 and be received by receiver 52. Additionally, the laser light L2 emitted by the laser transmitter 53 may also pass above the semiconductor wafer 20 and be detected by the receiver 54. This change in the detection pattern indicates that the support pads 1330 of the support pins 133 need to be replaced.

By utilizing the monitor system 5, users can determine the condition of the support pads 1330 and take appropriate action. This system provides a reliable and efficient method for monitoring the wear and tear of the support pads 1330, ensuring the smooth operation of the holders 13 and semiconductor wafer 20.

The above process is described in terms of the structure illustrated in FIG. 2 for illustrative purposes. The above process may utilize the structures illustrated in FIGS. 6A and 6B.

It will be further appreciated that the foregoing apparatus and system may be used in the EBR process. The wafer chuck assembly of the present disclosure may provide multiple-point contact between the bottom surface of the wafer and each holder, allowing for stable rotation of the wafer during the EBR process in the wafer chuck assembly. This configuration significantly reduces the probability of EBR alarms, with an approximate reduction of 80%. Further, the support pin of the holder may include a FFKM (perfluoroelastomer) material with anti-wear and anti-chemical corrosion properties. When the support pad 1330 are made from FFKM material, it significantly reduces the pad wear and extends the frequency of pad replacement. In addition, the wafer chuck assembly of the present disclosure may include a monitor system. The monitor system may monitor the usage status of support pads of the support pins in real-time and automatically. Users can utilize the monitor system to determine whether it is necessary to replace the support pads.

According to one embodiment, a chuck assembly comprises a hub, a plurality of arms mounted to the hub and a plurality of holders. Each arm extends outwardly from the hub, and each arm has a proximal end adjacent the hub and a distal end remote from the hub. Each holder is mounted at the distal end of each respective arm, and each holder has a plurality of support pins configured to support a wafer. According to one embodiment of the present disclosure, horizontal distances from each of the support pins to a center of the hub are substantially equal to each other. According to one embodiment of the present disclosure, the support pin comprises a FFKM (perfluoroelastomer) material. According to one embodiment of the present disclosure, the chuck assembly further comprises a monitor system configured to monitor the support pins. According to one embodiment of the present disclosure, the monitor system comprises a first laser transmitter configured to emit a first laser toward the support pins, a first laser receiver configured to receive the first laser emitted from the laser transmitter, a second laser transmitter configured to emit a second laser over the wafer supported by the support pin, and a second laser receiver configured to receive the second laser emitted from the second laser transmitter. According to one embodiment of the present disclosure, when the first laser emitted from the first laser transmitter reaches the first receiver and the second laser emitted from the second laser transmitter reaches the second receiver, the monitor system is configured to send an alarm that the support pins have worn down and require replacement. According to one embodiment of the present disclosure, a number of the support pins provided by each of the holders is two, three, or five.

According to another embodiment of the present disclosure, a chuck assembly comprises a rotatable hub, a plurality of support arms and a plurality of holders. Each of the support arms has a first end connected to the rotatable hub and a second end opposite to the first end. Each of the holders is attached to the second end of the chuck arm. The holders are configured to hold a wafer. Each of the holders comprises at least two support pads configured to provide a multiple-point contact between a bottom surface of the wafer and the holder when the wafer is held by the holders. According to another embodiment of the present disclosure, the at least two support pads directly contact the bottom of the wafer when the wafer is held by the holders. According to another embodiment of the present disclosure, a number of the support pads provided by each of the holders is two, three, or five. According to another embodiment of the present disclosure, the support pads are spaced at a distance from each other. According to another embodiment of the present disclosure, the distance is equal to or greater than a diameter of the support pad. According to another embodiment of the present disclosure, the support pad comprises a FFKM (perfluoroelastomer) material. According to another embodiment of the present disclosure, the chuck assembly comprises a monitoring system configured to monitor a wear condition of the support pads. According to another embodiment of the present disclosure, the monitoring system is configured to emit laser to sense the support pads and determine the wear condition of the support pads.

According to one embodiment of the present disclosure, a method of processing a wafer comprises: placing the wafer in a chuck assembly, the chuck assembly having chuck arms and a plurality of wafer holders at ends of the chuck arms, each of the wafer holders comprising at least two support pins, the wafer contacting an upper surface of the support pins; and rotating the chuck assembly and the wafer. According to one embodiment of the present disclosure, the method comprises: providing an etchant to an edge bevel region of the wafer while the wafer is rotated. According to one embodiment of the present disclosure, the support pin comprises an FFKM material. According to one embodiment of the present disclosure, the method comprises: monitoring a wear condition of the support pins by a laser transmitter and a laser receiver. According to one embodiment of the present disclosure, the method comprises providing an alarm when the laser receiver receives a laser emitted from the laser transmitter.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chuck assembly, comprising:
a hub;
a plurality of arms mounted to the hub, each arm extending outwardly from the hub, each arm having a proximal end adjacent the hub and a distal end remote from the hub; and
a plurality of holders, each holder mounted at the distal end of each respective arm, each holder having a plurality of support pins configured to support a wafer.

2. The chuck assembly of claim 1, wherein horizontal distances from each of the support pins to a center of the hub are substantially equal to each other.

3. The chuck assembly of claim 1, wherein the support pin comprises a FFKM (perfluoroelastomer) material.

4. The chuck assembly of claim 1, further comprising a monitor system configured to monitor the support pins.

5. The chuck assembly of claim 4, wherein the monitor system comprises:
a first laser transmitter configured to emit a first laser toward the support pins;
a first laser receiver configured to receive the first laser emitted from the laser transmitter;
a second laser transmitter configured to emit a second laser over the wafer supported by the support pins; and
a second laser receiver configured to receive the second laser emitted from the second laser transmitter, wherein a first laser path between the first laser transmitter and the first laser receiver is lower than a second laser path between the second laser transmitter and the second laser receiver relative to an upper surface of the plurality of holders.

6. The chuck assembly of claim 5, wherein, when the first laser emitted from the first laser transmitter reaches the first receiver and the second laser emitted from the second laser transmitter reaches the second receiver, the monitor system is configured to send an alarm.

7. The chuck assembly of claim 1, wherein a number of the support pins provided by each of the holders is two, three, or five.

8. A chuck assembly, comprising:
a rotatable hub;
a plurality of support arms, wherein each of the support arms has a first end connected to the rotatable hub and a second end opposite to the first end; and
a plurality of holders configured to hold a wafer, wherein each of the holders is attached to the second end of the chuck arm, wherein each of the holders comprises at least two support pads.

9. The chuck assembly of claim 8, wherein the at least two support pads directly contact the bottom of the wafer when the wafer is held by the holders.

10. The chuck assembly of claim 8, wherein a number of the support pads provided by each of the holders is two, three, or five.

11. The chuck assembly of claim 8, wherein the support pads are spaced apart from each other by a distance.

12. The chuck assembly of claim 11, wherein the distance is equal to or greater than a diameter of the support pad.

13. The chuck assembly of claim 8, wherein the support pad comprises a FFKM (perfluoroelastomer) material.

14. The chuck assembly of claim 8, further comprising a monitoring system configured to monitor a wear condition of the support pads.

15. The chuck assembly of claim 14, wherein the monitoring system is configured to emit laser to sense the support pads and determine the wear condition of the support pads.

16. A method of processing a wafer, the method comprising:
placing the wafer in a chuck assembly, the chuck assembly having chuck arms and a plurality of wafer holders at ends of each of the chuck arms, each of the wafer holders comprising at least two support pins, the wafer contacting an upper surface of the support pins; and
rotating the chuck assembly and the wafer.

17. The method of claim 16, further comprising:
providing an etchant to an edge bevel region of the wafer while the wafer is rotated.

18. The method of claim 17, wherein the support pins comprise an FFKM material.

19. The method of claim 17, further comprising:
monitoring a wear condition of the support pins by a laser transmitter and a laser receiver.

20. The method of claim 19, further comprising:
providing an alarm when the laser receiver receives a laser emitted from the laser transmitter.
